(19) United States
(12) Patent Application Publication
(10) Pub. No.: US 2008/0085572 A1
(43) Pub. Date: Apr. 10, 2008

(54) SEMICONDUCTOR PACKAGING METHOD BY USING LARGE PANEL SIZE

(75) Inventors: Wen-Kun Yang, Hsinchu City (TW); Chih-Wei Lin, Gueiren Township (TW); Chun-Hui Yu, (US)

Correspondence Address: KUSNER & JAFFE;HIGHLAND PLACE SUITE 310, 6151 WILSON MILLS ROAD, HIGHLAND HEIGHTS, OH, 44143, US

(73) Assignee: Advanced Chip Engineering Technology Inc.

(21) Appl. No.: 11/538,896

(22) Filed: Oct. 5, 2006

(51) Int. Cl. H01L 21/60

(52) U.S. Cl. 438/127; 438/613; 438/614

(57) ABSTRACT

The present invention discloses a semiconductor packaging method, comprises steps of back lapping a processed silicon wafer to a desired thickness. Then, the dice are separated from the processed and lapped wafer into a single die. Then, the dice are picked and placed on a tool, an active surface of the dice is attached on the tool. A molding is performed to mold the dice by molding material. The tool is then removed from the dice to form a small unit. The next step is to arrange a plurality of the small units on a carrier in a matrix from. Then, a build-up layer, a re-distribution layer are formed over the dice, followed by forming solder balls on the dice. Finally, the carrier is removed.

### FIELD OF THE INVENTION

This invention relates to a semiconductor packaging, and more particularly to a semiconductor packaging by using large panel size and lowest packaging cost per unit.

### BACKGROUND OF THE INVENTION

The earlier lead frame package technology is already not suitable for the advanced semiconductor dies due to the density of the terminals thereof is too high. Hence, a new package technology of BGA (Ball Grid Array) has been developed to satisfy the packaging requirement for the advanced semiconductor dies. The BGA package has an advantage of that the spherical terminals has a shorter pitch than that of the lead frame package, and the terminals of the BGA are unlikely to be damage and deform. In addition, the shorter signal transmitting distance benefits to raise the operating frequency to conform to the requirement of faster efficiency. Most of the package technologies divide dice on a wafer into respective dies and then to package and test the die respectively. Another package technology, called “Wafer Level Package (WLP)”, can package the dies on a wafer before dividing the dice into respective individual die. The WLP technology has some advantages, such as a shorter producing cycle time, lower cost, and no need to under-fill or molding.

FIG. 1 shows a conventional strip molding method for semiconductor package disclosed by U.S. Pat. No. 6,271,469. In the method, a tape 104 is abutted against an active surface 106 of a microelectronic die 102 to protect the microelectronic die active surface 106 from any contaminants. The microelectronic die active surface 106 has at least one contact 108 disposed thereon. The contacts 108 are in electrical contact with integrated circuitry (not shown) within the microelectronic die 102. The protective film 104 may have a weak adhesive, similar to protective films used in the industry during wafer dicing, which attaches to the microelectronic die active surface 106. This adhesive-type film may be applied prior to placing the microelectronic die 102 in a mold used for the encapsulation process. The protective film 104 may also be a non-adhesive film, such as ETFE (ethylene-tetrafluoroethylene) or Teflon, RTM film, which is held on the microelectronic die active surface 106 by an inner surface of the mold during the encapsulation process.

Turning to FIG. 2, the tape of FIG. 1 would be placed on the package area 202 of the molding tools 200 (strip form). Turn to FIG. 3, the microelectronic die 102 is then encapsulated with an encapsulating material 112, such as plastics, resins, and the like, as shown in FIG. 3, that covers a back surface 114 and side(s) 116 of the microelectronic die 102. The encapsulation of the microelectronic die 102 may be achieved by any known process, including but not limited to injection, transfer, and compression molding. The encapsulation material 112 provides mechanical rigidity, protects the microelectronic die 102 from contaminants, and provides surface area for the build-up of trace layers.

However, the method is too complicated, and the molding tool 200 has a lot of spacing 204 between the package areas 202. The spacing 204 occupies too much space, and therefore, the number of packing die will be decreased. Another possible problem is the dice accuracy on the tape during molding process, it may cause the dice shift and twist and causing the yield loss of build-up layer and re-distribution process.

### SUMMARY OF THE INVENTION

The present invention discloses a semiconductor packaging method, comprises steps of back lapping a processed silicon wafer to a desired thickness. Then, the dice are separated from the processed and lapped wafer into a single die. Then, the dice are picked and placed on a tool, an active surface of the dice is attached on the tool. A molding is performed to mold the dice by molding material. The tool is then removed from the dice to form a small unit. The next step is to arrange a plurality of the small units on a carrier in a matrix from. Then, a build-up layer, a re-distribution layer are formed over the dice, followed by forming solder balls on the dice. Finally, the carrier is removed, and the dice are separated.

The material to attach the dice include water soluble glue, chemical solution soluble glue, re-workable glue, high melting point wax, the material of the removable tools is glass, metal, silicon, ceramic or PCB and the material of the carrier includes glass. In one example, the build-up layer and re-distribution layer are formed within equipment for manufacturing LCD display panel. Alternatively, the build-up layer and re-distribution layer are formed within the equipment for PCB type equipment.

### BRIEF DESCRIPTION OF THE DRAWINGS

The above objects, and other features and advantages of the present invention will become more apparent after reading the following detailed description when taken in conjunction with the drawings, in which:

FIG. 1-FIG. 3 are a schematic diagrams of a conventional package structure.

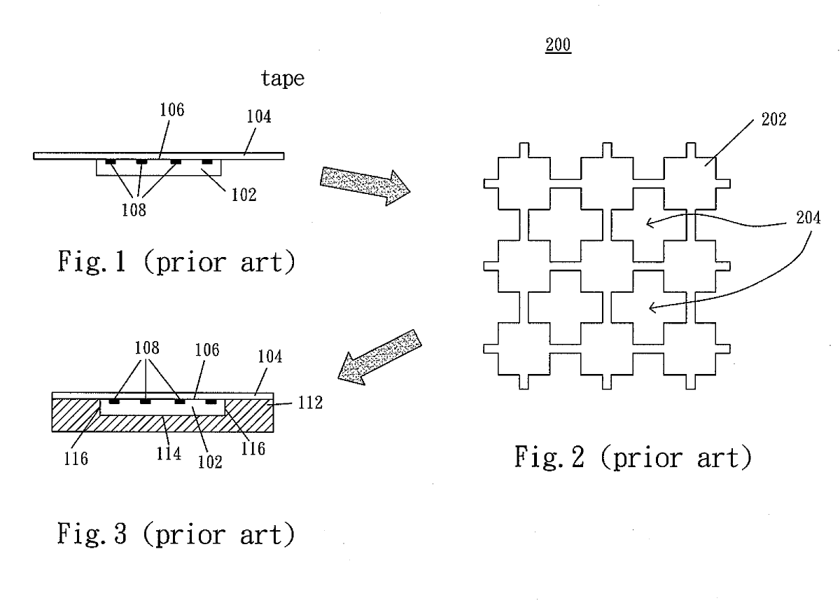

FIG. 4 is a schematic diagram showing the step of attaching dice on a tool according to the present invention.

FIG. 5A-5B are schematic diagrams showing the molding step according to the present invention.

FIG. 6 is schematic diagram showing the step of arranging small units on a carrier in a matrix form according to the present invention.

FIG. 7 is schematic diagram showing the steps of forming build-up layer, solder balls according to the present invention.

FIG. 8 is schematic diagram showing the step of separating the dice according to the present invention.

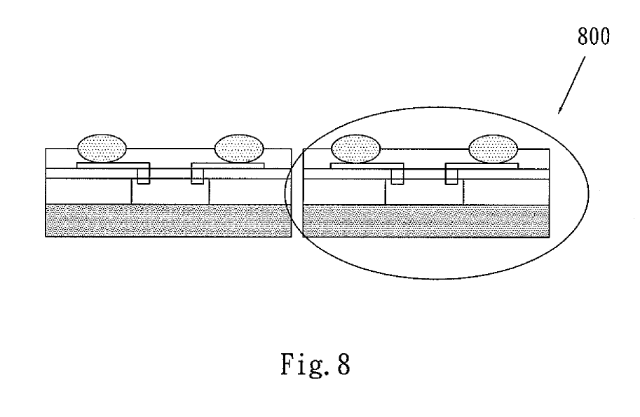

### DETAILED DESCRIPTION OF THE PREFERRED EMBODIMENT

The present invention is described with the preferred embodiments and accompanying drawings. It should be appreciated that all the embodiments are merely used for illustration. Hence, the present invention can also be applied to various embodiments other than the preferred embodiments. Besides, the present invention is not limited to any embodiment but to the appending claims and their equivalents.

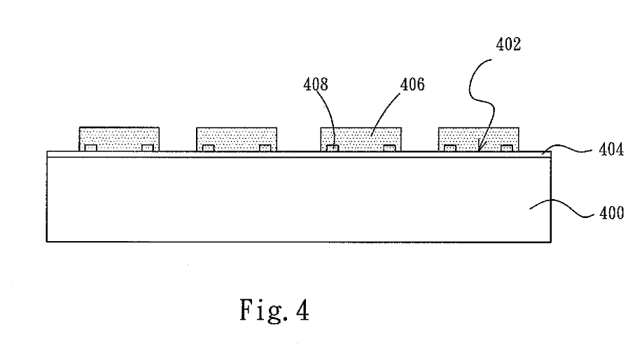

In order to achieve the present invention, a large panel size glass, such as for LCD, is prepared. Then, a back lapping process is performed to back lap the processed silicon wafer to a desired thickness, followed by dicing the processed wafer and lapped wafer into a plurality of single dice. Please refer to FIG. 4, a tool 400 for die re-distribution is prepared, the tool 400 has alignment patterns (not shown) on the top surface for the alignment during place the die. The separated dice are picked and placed on the tool 400 with the active surface 402 up site down on the tool. A glue material 404 is coated on the tool surface for temporary stick the dice, and it can be released under the releasing condition. From the FIG. 3, the die 406 includes pads 408 on the active surface. The active surface 402 of the die is up site down and is attached on the glue material 402. The method allows the space among the dice as smaller as possible by the pick and place system.

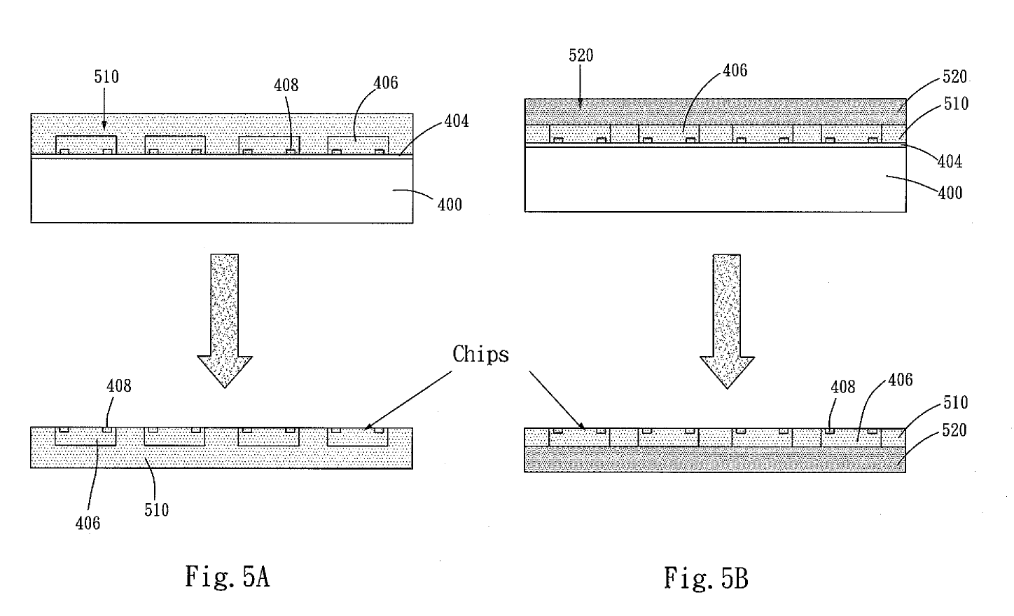

The material of the glue may be elastic material such as water soluble glue, re-workable glue, high melting point wax, chemical solution soluble glue etc., the material for the rigid tool could be glass, metal, alloy, silicon, ceramic or PCB. The next step is to mold the dice, the molding material such as resin 510 is printed or molded over the tool 400 and dice 406 as shown in FIG. 5A. Then, the tool 400 is released from the dice by treating the tool within a solution, water, high temperature environment depending on the glue selected by the user. Alternatively, the resin 510 is partially removed to a desired thickness and then a substrate 520 is attached on the dice or the molding material (core paste) 510, as shown in the FIG. 5B. The substrate 520 could be glass, metal, alloy, silicon, ceramic or PCB. The material for the attached substrate can be the same as the core paste. In one embodiment, the material 520 could be glass, metal, alloy, ceramic or PCB.

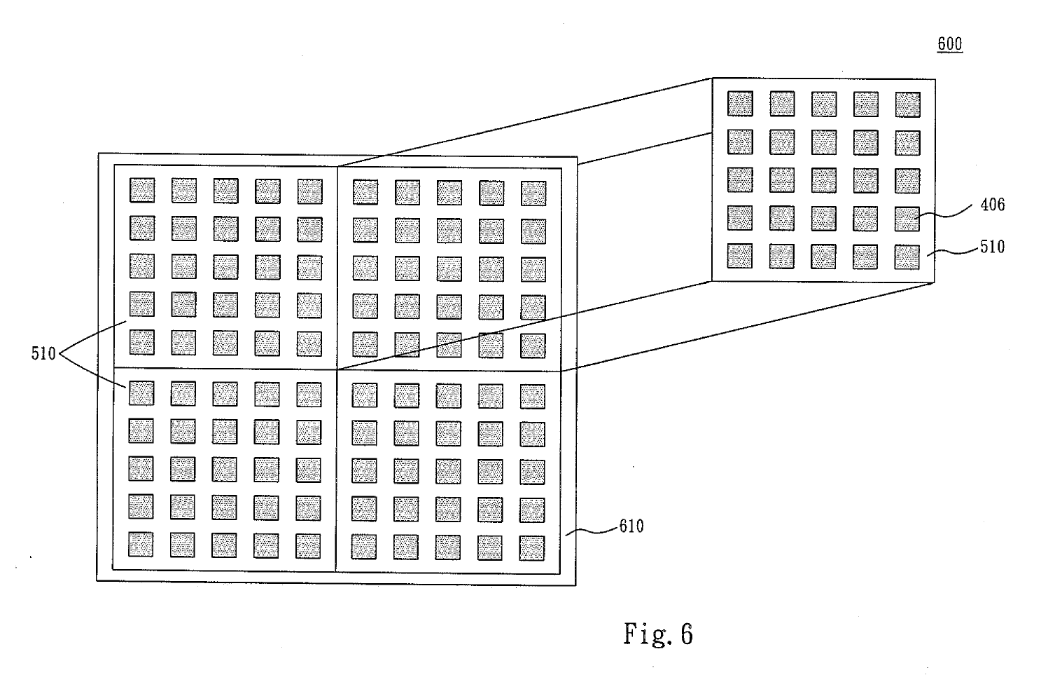

Please refer to FIG. 6, the top view of the molding material 510 with dice 406 arranged thereon is shown. It can be seen, the dice 406 are arranged in a matrix form, the pitch between the dice 406 can be determined by the user in designed value, and the present invention may achieve the purposes of space saving and cost reduction and high accuracy during place the dice on the tool. The single unit substrate 500 is shown on the up-right side of the illustration. A plurality of the single unit 600 can be arranged to become a large size panel on a glass carrier 610. The small single units 600 with dice are arranged on the carrier 610 in a matrix form. The carrier is preferably a glass. Thus, a batch process can be achieved by the present invention. The throughput is therefore significantly improved, and the cost is also reduced. For the LCD type process, several small units 600 can be arranged on the LCD glass 610 to form a large size substrate for subsequent process. In the scheme, the LCD glass is treated as the carrier during the process before sawing (singulation) the panel. Alternatively, the single unit 600 can be processed directly without forming the large matrix form as mentioned above.

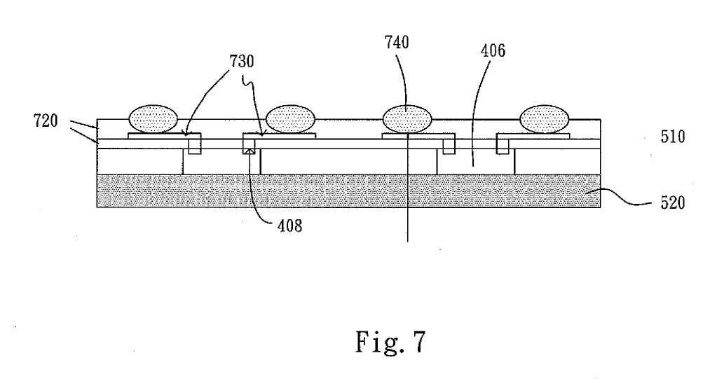

Next, a build up layer process and electro plating process are performed to create build-up layer 720 and re-distribution layer 730, as shown in FIG. 7. The process is well-known in the art, the detailed description is omitted. Subsequently, solder ball placement and solder paste printing steps are performed, followed by re-flow the solder by IR to construct the final terminals. The solder balls 740 will be formed over the re-distribution layer. The singulation process is next used to separate the dice to form an individual chip 800 after final test. If the method of employing the glass carrier is employed, the glass carrier has to be removed before separating the dice.

The equipments for manufacturing LCD panel and PCB/substrate are adapted to the build-up layer, coating, exposure, sputtering and etching process without employing the semiconductor equipment. As we are known, the semiconductor equipment is highly expensive to the LCD equipment. The manufacture cost can be significantly reduced by the present invention. The present invention suggests the usage of glass carrier method, the rectangular type substrate may carrier more chip thereon than the wafer (circle) type substrate. Therefore, more package units can be processed simultaneously, the batch process is according achieved. The alignment accuracy of the LCD display panel type is around 1 micron meter, and the PCB/substrate type is around 2 micron meters. The accuracy of the present invention may meet the requirement of build-up layers on the chip.

Although specific embodiments have been illustrated and described, it will be obvious to those skilled in the art that various modifications may be made without departing from what is intended to be limited solely by the appended claims.

Having described the invention, the following is claimed:

1. A semiconductor packaging method, comprising:
picking and placing dice on a tool, an active surface of the dice is attached on said tool;
molding said dice by a molding material;
removing said tool from said dice to form a unit;
arranging a plurality of said units on a carrier in a matrix from;
forming a build-up layer, a re-distribution layer over said dice over said carrier;
forming solder balls on said dice;
removing said carrier; and
separating said dice.

2. The semiconductor packaging method in claim 1, wherein material to attach said dice include water soluble glue, chemical solution soluble glue, re-workable glue or high melting point wax.

3. The semiconductor packaging method in claim 1, wherein material of said removable tools is glass, metal, silicon, ceramic or PCB.

4. The semiconductor packaging method in claim 1, further comprising the steps before attaching said dice on said tool:
back lapping a processed silicon wafer to a desired thickness;
dicing said processed and lapped wafer into a single die.

5. The semiconductor packaging method in claim 1, wherein material of said carrier includes glass.

6. The semiconductor packaging method in claim 1, wherein said molding step includes filling resin between said dice and back side of dice.

7. The semiconductor packaging method in claim 1, further comprising the step forming a substrate on said molding material before removing said tool.

8. The semiconductor packaging method in claim 1, wherein said build-up layer and re-distribution layer are formed within the equipment for manufacturing LCD display panel or PCB/Substrate manufacturing equipment.

9. A semiconductor packaging method, comprising:
picking and placing dice on a tool, an active surface of the dice is attached on said tool;
molding said dice by a molding material;
removing said tool from said dice to form a unit;
forming a build-up layer, a re-distribution layer over said dice over said unit;
forming solder balls on said dice; and
separating said dice.

10. The semiconductor packaging method in claim 9, wherein material to attach said dice include water soluble glue, chemical solution soluble glue, re-workable glue or high melting point wax.

11. The semiconductor packaging method in claim 9, wherein material of said removable tools is glass, metal, silicon, ceramic or PCB.

12. The semiconductor packaging method in claim 9, further comprising the steps before attaching said dice on said tool:
back lapping a processed silicon wafer to a desired thickness;
dicing said processed and lapped wafer into a single die.

13. The semiconductor packaging method in claim 9, further comprising the step forming a substrate on said molding material before removing said tool.

14. The semiconductor packaging method in claim 9, wherein said molding step includes filling resin between said dice and back side of dice.

15. The semiconductor packaging method in claim 9, wherein said build-up layer and re-distribution layer are formed within the equipment for manufacturing LCD display panel or PCB/Substrate manufacturing equipment.
